(19) United States
(12) Patent Application Publication
(10) Pub. No.: US 2006/0264028 A1
(43) Pub. Date: Nov. 23, 2006

(54) Energy beam treatment to improve the hermeticity of a hermetic layer

(75) Inventors: Laura M. Matz, Murphy, TX (US); Ting Y. Tsui, Garland, TX (US); Robert Kraft, Plano, TX (US)

Correspondence Address: TEXAS INSTRUMENTS INCORPORATED, P O BOX 655474, M/S 3999, DALLAS, TX, 75265, US

(73) Assignee: Texas Instruments, Incorporated, Dallas, TX (US)

(21) Appl. No.: 11/134,566

(22) Filed: May 20, 2005

(51) Int. Cl. H01L 21/469

(52) U.S. Cl. 438/622; 438/786; 438/798

(57) ABSTRACT

The present invention provides a process for increasing the hermeticity of a hermetic layer, a method for manufacturing an interconnect structure, and a method for manufacturing an integrated circuit. The process for increasing the hermeticity of the hermetic layer, without limitation, includes providing a hermetic layer over a substrate (160), the hermetic layer having a initial hermeticity, and subjecting the hermetic layer to an energy beam, thereby causing the initial hermeticity to improve (170).

### TECHNICAL FIELD OF THE INVENTION

The present invention is directed, in general, to a process for increasing the hermeticity of a hermetic layer and, more specifically, to a process for increasing the hermeticity of a hermetic layer using an energy beam.

### BACKGROUND OF THE INVENTION

The push to submicron multilevel metallized interconnections, such as lines, via, and trenches, and the desire to produce faster semiconductor devices, has resulted in a shift toward the use of copper for making electrical interconnections in ultra-large scale integration circuits. Copper interconnects, however, because of their oxidizing nature, often require a hermetic layer be formed thereover after each metallization level. The hermetic layer serves as a barrier for moisture or oxygen diffusion into the underlying copper layer during damascene processing.

There is currently a tradeoff in the industry that the hermetic layer be thick enough to provide the requisite amount of hermetic protection for the copper interconnects, but thin enough to minimize the contribution of the hermetic layer to the dielectric constant (k-effective) of the dielectric stack, and thus does not increase the capacitance and therefore RC delay. In the current technology nodes, such as the 90 nm nodes and 65 nm nodes, a single hermetic layer thickness accomplishes both the requisite amount of hermetic protection and the requisite k-effective. For example, a 60 nm thick SiCN hermetic layer is about as thin as can be used to provide both the requisite amount of hermetic protection and the required k-effective.

Unfortunately, as the next generation technology nodes are introduced, such as the 45 nm node, a single hermetic layer thickness will not accomplish both the requisite amount of hermetic protection and the decreasing k-effective requirement. When this occurs, the industry will be forced to decide whether to accept limited hermeticity protection in lieu of decreased k-effective values, or vice versa. Neither scenario is appealing to the industry.

Accordingly, what is needed in the art is a new hermetic layer or process for manufacture therefore, that would accommodate both the requisite amount of hermetic protection and the decreasing k-effective requirement.

### SUMMARY OF THE INVENTION

To address the above-discussed deficiencies of the prior art, the present invention provides a process for increasing the hermeticity of a hermetic layer, a method for manufacturing an interconnect structure, and a method for manufacturing an integrated circuit. The process for increasing the hermeticity of the hermetic layer, without limitation, includes providing a hermetic layer over a substrate, the hermetic layer having an initial hermeticity, and subjecting the hermetic layer to an energy beam, thereby causing the initial hermeticity to improve. The method for manufacturing the interconnect structure, in addition to the elements of the aforementioned process, further includes forming an interconnect located between the substrate and the hermetic layer.

As indicated above, another embodiment of the present invention is a method for manufacturing an integrated circuit. The method for manufacturing the integrated circuit may include: (1) forming transistor devices over a substrate, (2) forming a dielectric layer over the transistor devices, (3) forming a copper damascene interconnect in the dielectric layer, (4) providing a hermetic layer over the copper damascene interconnect, the hermetic layer having a initial hermeticity, and (5) subjecting the hermetic layer to an energy beam, thereby causing the initial hermeticity to improve.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

FIG. 1 illustrates a flow chart setting out one embodiment for manufacturing an interconnect structure in accordance with the principles of the present invention; and

FIG. 2 illustrates an exemplary cross-sectional view of an integrated circuit (IC) incorporating interconnect structures constructed according to the principles of the present invention.

### DETAILED DESCRIPTION

The present invention is based, at least in part, on the recognition that an energy beam treatment or curing of a thinner than normal hermetic layer might balance the tradeoff between effective dielectric constant (k-effective) and hermeticity, which are both traditionally related to the thickness of the hermetic layer. The present invention specifically recognized that thinner hermetic layers having an initial hermeticity could be treated with an energy beam, the energy beam thereby causing the thinner hermetic layer having the initial hermeticity to have an improved hermeticity. Accordingly, the thinner hermetic layers would have the desired k-effective, but would also have the requisite hermeticity required to protect the interconnect from external environments.

A hermetic layer, as used herein, is any layer that may impede the diffusion of moisture or oxygen within a stack of layers. For instance, in a semiconductor device, the hermetic layer may be placed in such a position as to impede the diffusion of moisture or oxygen from an interlevel dielectric layer to an underlying copper layer, thereby inhibiting copper oxidation. The hermeticity of a given hermetic layer is a measurement of the ability of the hermetic layer to impede the diffusion of moisture or oxygen over time. One method for measuring a hermetic layer's hermeticity is to place the hermetic layer over a tensile dielectric material (e.g., TEOS or OSG) and measure the tensile dielectric material's stress as a function of time. As moisture or oxygen diffuses into the hermetic layer the diffusion will show up as stress change in the dielectric layer. This is one appropriate measurement technique of a material's hermeticity. Other known measurement techniques may also be used to measure a given hermetic layer's hermeticity. In any event, the novel features of the present invention cause a hermetic layer's hermeticity to improve.

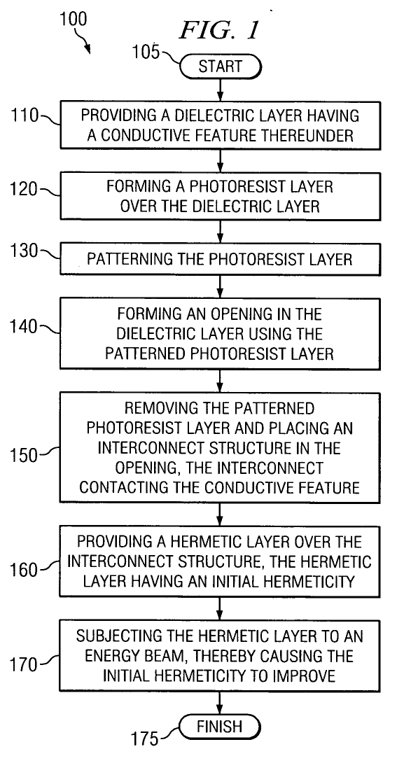

Turning now to FIG. 1, illustrated is a flow chart 100 setting out one embodiment for manufacturing an interconnect structure, such as a damascene interconnect structure, in accordance with the principles of the present invention. The method for manufacturing the interconnect structure described in the flow chart 100 of FIG. 1 also encompasses a unique process for increasing the hermeticity of a hermetic layer in accordance with the principles of the present invention. Accordingly, the two will be discussed together.

The method for manufacturing an interconnect structure in accordance with the principles of the present invention begins in a start step 105. Thereafter, in a step 110, a dielectric layer having a conductive feature there under is provided. In many embodiments of the present invention, the dielectric layer is a low dielectric constant (k) layer. As used herein, a low dielectric constant (k) layer is a layer having a dielectric constant (k) less than silicon dioxide, and thus a dielectric constant (k) of less than about 4.0. The inclusion of the low dielectric constant (k) layer may be used to further reduce the k-effective discussed above. As previously mentioned, positioned under the low dielectric constant (k) layer is the conductive feature. While the conductive feature may comprise almost any conductive material, certain embodiments of the present invention benefit the most when the conductive feature is a copper containing conductive feature.

After step 110, a photoresist layer is formed over the dielectric layer in a step 120. The photoresist layer may be any known or hereafter discovered photoresist layer that is in accordance with the principles of the present invention. After forming the photoresist layer in the step 120, the photoresist layer is patterned in a step 130. In an exemplary embodiment the photoresist layer is patterned to have an opening therein, the opening being located over the conductive feature.

In a step 140, the patterned photoresist layer is conventionally used to form an opening in the dielectric layer. Preferably, this is accomplished by subjecting the dielectric layer to CF₄, CHF₃, or other fluorinated compound plasma environment, as well as other plasma environments known in the art to etch or remove dielectric materials. Nevertheless, any other known or hereafter discovered process could be used to form the opening in the dielectric layer. In the aforementioned embodiment wherein the opening in the patterned photoresist layer is located over the conductive feature the opening in the dielectric layer should also be located over the conductive feature.

After forming the opening in the dielectric layer in the step 140, the photoresist layer is removed and an interconnect is formed within the opening in a step 150. The interconnect may comprise a variety of different structures while staying within the scope of the present invention. For example, the interconnect may comprise both a conventional barrier/adhesion layer located along the sidewalls and bottom of the opening in the dielectric layer, and a conventional conductive plug filling the remainder of the opening. In this embodiment, without limitation, the conventional barrier/adhesion layer might comprise a tantalum/tantalum nitride stack and the conductive plug might comprise copper or copper doped aluminum. Nevertheless, other barrier/adhesion layer materials and conductive plug materials are within the scope of the present invention. Similarly, the barrier adhesion layer might not be used, and thus the conductive plug would be formed directly in the opening in the dielectric layer.

Those skilled in the pertinent art are aware of the many different processes that might be used to form the conductive plug. In the embodiment wherein copper is the conductive plug material, a copper electroplating process using a copper seed layer, and a copper electroplating solution could be used. In this embodiment a blanket layer of copper material would typically be formed in the opening and over an upper surface of the dielectric layer. In certain embodiment, a conventional chemical-mechanical polishing (CMP) process could be used to remove any undesired copper. Other embodiments might exists wherein no CMP process was required.

After forming the interconnect in the step 150, a hermetic layer is provided over the interconnect in a step 160. The hermetic layer, as formed, would have an initial hermeticity, the value of which obviously depends on the thickness and material composition of the hermetic layer. Accordingly, the thickness and material composition of the hermetic layer may vary and remain within the scope of the present invention. For instance, one embodiment exists wherein the hermetic layer comprises a SiCN hermetic layer. Another different embodiment exists, however, wherein the hermetic layer comprises a SiCO hermetic layer. In those instances wherein the hermetic layer comprises a SiCO hermetic layer, another oxygen barrier layer may be required between the SiCO hermetic layer and the interconnect. Still other embodiments exist wherein the hermetic layer comprises even different materials.

With the different hermetic layer materials come different hermetic layer thicknesses. Nevertheless, the requisite thicknesses of the hermetic layer according to the present invention should be less than the requisite thickness of conventional hermetic layers. Accordingly, it is believed that the hermetic layer may have a thickness less than about 55 nm, and after the unique energy beam treatment accommodate both the k-effective requirements and hermeticity requirements of the industry. In an advantageous embodiment, it is believed that the hermetic layer may have a thickness of about 45 nm or less, or in an exemplary embodiment a thickness of about 30 nm or less, while achieving the requirements of the industry.

Those skilled in the art understand the process that could be used to manufacture the hermetic layer. For instance, in one embodiment the hermetic layer is deposited using a plasma-enhanced chemical vapor deposition (PECVD) process. Other embodiments might exist, however, wherein the hermetic layer is deposited using a conventional physical vapor deposition (PVD) process.

It should be noted at this point that the hermetic layer, in certain embodiments, may not only act as a hermetic film for the interconnect structure, but it may also act as an etch stop for the formation of subsequent interconnect structures or a barrier layer. Accordingly, as used herein, the term hermetic layer includes those layers that provide hermetic benefits and do not act as an etch stop layer or barrier layer, as well as those layers that provide both hermetic benefits and act as an etch stop layer and/or barrier layer. In reality, almost any type of material may act as a hermetic layer, whether it provides other functions or not. As initially written, the present invention is intended to cover such layers.

After forming the hermetic layer having the initial hermeticity in the step 160, the hermetic layer may be subjected to an energy beam in a step 170. The energy beam, in accordance with the principles of the present invention, is designed to improve the initial hermeticity of the hermetic layer. Accordingly, a hermetic layer subjected to the energy beam will have better hermeticity measurements than a similar hermetic layer not subjected to the energy beam.

The energy beam, according to the present invention, may comprise a plurality of different energy beams. For instance, one embodiment exists wherein the energy beam is an ultraviolet (UV) energy beam. In such an embodiment the UV energy beam could be projected on a portion or the entire hermetic layer using a wavelength between about 180 nm and about 780 nm. Similarly, the UV energy beam could be projected using a plurality of wavelengths between the aforementioned range. The UV energy beam may generally be conducted for a time period ranging from about 5 seconds to about 60 minutes. Likewise, the temperature associated with the UV energy beam exposure should be less than about 500° C. Other processing conditions outside of the disclosed ranges may, nevertheless, also be used.

Another embodiment of the invention exists wherein the energy beam is an electron beam. In one exemplary embodiment the electron beam is a focused electron beam that is accurately moved across the portions of the hermetic layer that need treatment. In most instances, the focused electron beam would contact the entire hermetic layer, thereby increasing the hermeticity of the entire hermetic layer. There may also be other embodiments wherein the electron beam is not a tightly focused electron beam, and thus the electron beam has a broader coverage area that is able to flood the surface with the electrons.

In the embodiment wherein the electron beam is used to treat the hermetic layer, the electron beam might use a dose ranging from about 5 μC/cm² to about 2000 μC/cm². This dose is representative of the amount of energy per unit area that is being imparted on the hermetic layer. Other conditions that might be used include conducting the electron beam in an enclosure maintained at a pressure approaching a vacuum (e.g., about 0.01 mT). Similarly, the chamber may be maintained at a temperature ranging from about 200° C. to about 500° C. Likewise, a voltage differential between two plates of about 3.5 kV might cause the electron beam to have a current of about 3 mA. Other processing conditions outside of the previously discussed ranges are, however, within the purview of the present invention.

After subjecting the hermetic layer to the energy beam in the step 170, the process could continue with the formation of another dielectric layer over the hermetic layer and thereafter return back to step 120, or in an alternative embodiment stop in finish step 175. Those skilled in the art understand that the hermetic layer is often located over each metal level in an integrated circuit. Accordingly, the flow diagram 100 of FIG. 1 may, in whole or part, be conducted a number of different times before the finish step 175 is conducted.

The unique aspects of the present invention provide many different benefits. First, and possibly foremost, the unique use of the energy beam allows the industry to accommodate both the desire for thinner hermetic layers for k-effective purposes, but the desire for adequate hermetic properties. However, in achieving both of these properties, the industry remains able to use convention hermetic layer materials. Accordingly, the industry remains able to use the same hardware, as well as is able to benefit from the learning curve of the film characteristics from previous nodes. Additionally, it is believed that the energy beam treatment may be added to the traditional process flows, and in one embodiment into the hermetic layer deposition tool, with minimal impact.

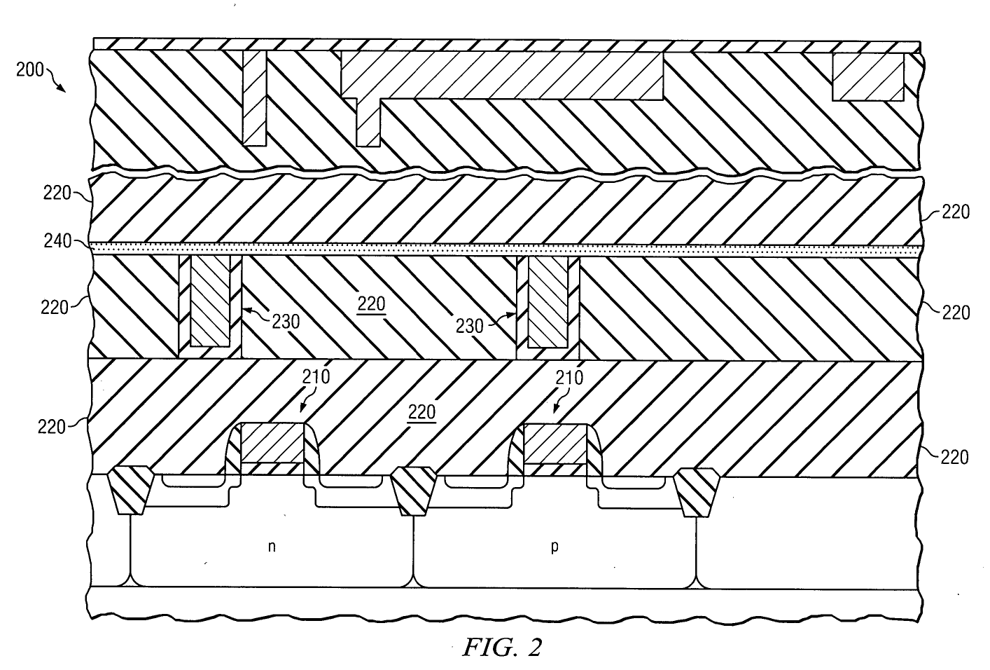

Referring now to FIG. 2, illustrated is an exemplary cross-sectional view of an integrated circuit (IC) 200 incorporating interconnect structures 230 constructed according to the principles of the present invention. The IC 200 may include devices, such as transistors used to form CMOS devices, BiCMOS devices, Bipolar devices, as well as capacitors or other types of devices. The IC 200 may further include passive devices, such as inductors or resistors, or it may also include optical devices or optoelectronic devices. Those skilled in the art are familiar with these various types of devices and their manufacture. In the particular embodiment illustrated in FIG. 2, the IC 200 includes transistor devices 210 having dielectric layers 220 located thereover. Additionally, interconnect structures 230 are located within the dielectric layers 220 to interconnect various devices, thus, forming the operational integrated circuit 200. Furthermore, a hermetic layer 240 having been subjected to an energy beam to improve its hermeticity is located over the interconnect structures 230.

Although the present invention has been described in detail, those skilled in the art should understand that they can make various changes, substitutions and alterations herein without departing from the spirit and scope of the invention in its broadest form.

What is claimed is:

1. A process for improving the hermeticity of a hermetic layer, comprising:
providing a hermetic layer over a substrate, the hermetic layer having a initial hermeticity; and
subjecting the hermetic layer to an energy beam, thereby causing the initial hermeticity to improve.

2. The process as recited in claim 1 wherein subjecting the hermetic layer to an energy beam includes subjecting the hermetic layer to an ultraviolet (UV) energy beam.

3. The process as recited in claim 2 wherein subjecting the hermetic layer to an ultraviolet (UV) energy beam includes subjecting the hermetic layer to an ultraviolet (UV) energy beam having a wavelength between about 180 nm and about 780 nm.

4. The process as recited in claim 2 wherein subjecting the hermetic layer to an ultraviolet (UV) energy beam includes subjecting the hermetic layer to an ultraviolet (UV) energy beam for a time period ranging from about 5 seconds to about 60 minutes.

5. The process as recited in claim 2 wherein subjecting the hermetic layer to an ultraviolet (UV) energy beam includes subjecting the hermetic layer to an ultraviolet (UV) energy beam using a temperature of less than about 500° C.

6. The process as recited in claim 1 wherein subjecting the hermetic layer to an energy beam includes subjecting the hermetic layer to an electron beam.

7. The process as recited in claim 6 wherein subjecting the hermetic layer to an electron beam includes subjecting the hermetic layer to an electron beam using a dose ranging from about 5 μC/cm² to about 2000 μC/cm².

8. The process as recited in claim 6 wherein subjecting the hermetic layer to an electron beam includes subjecting the hermetic layer to an electron beam using a temperature ranging from about 200° C. to about 500° C.

9. The process as recited in claim 1 wherein the hermetic layer is a SiCN hermetic layer.

10. The process as recited in claim 1 wherein the hermetic layer is a SiCO hermetic layer.

11. A method for manufacturing an interconnect structure, comprising:
forming an interconnect within an opening in a dielectric layer;
providing a hermetic layer over the interconnect, the hermetic layer having an initial hermeticity; and
subjecting the hermetic layer to an energy beam, thereby causing the initial hermeticity to improve.

12. The method as recited in claim 11 wherein subjecting the hermetic layer to an energy beam includes subjecting the hermetic layer to an ultraviolet (UV) energy beam.

13. The method as recited in claim 12 wherein subjecting the hermetic layer to an ultraviolet (UV) energy beam includes subjecting the hermetic layer to an ultraviolet (UV) energy beam having a wavelength between about 180 nm and about 780 nm.

14. The method as recited in claim 12 wherein subjecting the hermetic layer to an ultraviolet (UV) energy beam includes subjecting the hermetic layer to an ultraviolet (UV) energy beam for a time period ranging from about 5 seconds to about 60 minutes.

15. The method as recited in claim 12 wherein subjecting the hermetic layer to an ultraviolet (UV) energy beam includes subjecting the hermetic layer to an ultraviolet (UV) energy beam using a temperature of less than about 500° C.

16. The method as recited in claim 11 wherein subjecting the hermetic layer to an energy beam includes subjecting the hermetic layer to an electron beam.

17. The method as recited in claim 16 wherein subjecting the hermetic layer to an electron beam includes subjecting the hermetic layer to an electron beam using a dose ranging from about 5 μC/cm² to about 2000 μC/cm².

18. The method as recited in claim 16 wherein subjecting the hermetic layer to an electron beam includes subjecting the hermetic layer to an electron beam using a temperature ranging from about 200° C. to about 500° C.

19. A method for manufacturing an integrated circuit, comprising:
forming transistor devices over a substrate;
forming a dielectric layer over the transistor devices;
forming a copper damascene interconnect in the dielectric layer;
providing a hermetic layer over the copper damascene interconnect, the hermetic layer having an initial hermeticity; and
subjecting the hermetic layer to an energy beam, thereby causing the initial hermeticity to improve.

20. The method as recited in claim 19 wherein subjecting the hermetic layer to an energy beam includes subjecting the hermetic layer to an ultraviolet (UV) energy beam or an electron beam.
